(19) United States
(12) Patent Application Publication
(10) Pub. No.: US 2026/0068694 A1
(43) Pub. Date: Mar. 5, 2026

(54) Semiconductor Devices and Methods for Manufacturing Thereof

(71) Applicant: Infineon Technologies Austria AG, Villach (AT)

(72) Inventors: Suzanne Mary Valmores Basalo, Cebu, (PH); Pei Wen Tiw, Durian Tunggal (MY); Emmanuel Inoferio Livelo, Batu Berendam (MY); John Villa Badinas, Talisay City (PH); Rowel Tabajonda, Villach (AT)

(21) Appl. No.: 19/311,315

(22) Filed: Aug. 27, 2025

(30) Foreign Application Priority Data
Sep. 5, 2024 (DE) 102024125515.3

(51) Int. Cl. H01L 23/495; H01L 21/48; H01L 23/31

(52) U.S. Cl. CPC H01L 23/49568

(57) ABSTRACT

A semiconductor device includes a leadframe, a first semiconductor chip arranged above a mounting surface of the leadframe, and a heatsink arranged above a top surface of the first semiconductor chip facing away from the mounting surface of the leadframe. At least one first lead of the leadframe extends towards a bottom surface of the heatsink facing the mounting surface of the leadframe. The at least one first lead is mechanically coupled to the bottom surface of the heatsink.

### TECHNICAL FIELD

The present disclosure relates to semiconductor devices and methods for manufacturing semiconductor devices.

### BACKGROUND

The development of semiconductor devices and semiconductor packages is moving towards ever smaller dimensions. At the same time, requirements for efficiency, electrical properties and thermal management of the semiconductor devices need to be fulfilled. Against this background, it may be desirable to provide semiconductor devices of reduced size, while meeting specified requirements. More particular, it may be desirable to improve a thermal management of the semiconductor devices. In addition, it may be desirable to provide simple and cost efficient methods for a fabrication of the semiconductor devices.

### SUMMARY

An aspect of the present disclosure relates to a semiconductor device. The semiconductor device comprises a leadframe, a first semiconductor chip arranged above a mounting surface of the leadframe, and a heatsink arranged above a top surface of the first semiconductor chip facing away from the mounting surface of the leadframe. At least one first lead of the leadframe extends towards a bottom surface of the heatsink facing the mounting surface of the leadframe. The at least one first lead is mechanically coupled to the bottom surface of the heatsink.

A further aspect of the present disclosure relates to a method for manufacturing a semiconductor device. The method comprises providing a leadframe, arranging a first semiconductor chip above a mounting surface of the leadframe, arranging a heatsink above a top surface of the first semiconductor chip facing away from the mounting surface of the leadframe, wherein at least one first lead of the leadframe extends towards a bottom surface of the heatsink facing the mounting surface of the leadframe, and mechanically coupling the at least one first lead to the bottom surface of the heatsink.

Those skilled in the art will recognize additional features and advantages upon reading the following detailed description, and upon viewing the accompanying drawings.

### BRIEF DESCRIPTION OF THE DRAWINGS

Devices and methods in accordance with the disclosure are described in more detail below based on the drawings. The elements of the drawings are not necessarily to scale relative to each other. Similar reference numerals may designate corresponding similar parts. The technical features of the various illustrated examples may be combined unless they exclude each other and/or can be selectively omitted if not described to be necessarily required.

FIG. 1 includes FIGS. 1A and 1B schematically illustrating different views of a semiconductor device 100 in accordance with the disclosure.

FIG. 2 includes FIGS. 2A to 2G schematically illustrating different views and a circuit diagram of a semiconductor device 200 in accordance with the disclosure.

FIG. 3 includes FIGS. 3A to 3G schematically illustrating different views and a circuit diagram of a semiconductor device 300 in accordance with the disclosure.

FIG. 4 illustrates a flowchart of a method for manufacturing a semiconductor device in accordance with the disclosure.

### DETAILED DESCRIPTION

In the following detailed description, reference is made to the accompanying drawings, in which are shown by way of illustration specific aspects in which the disclosure may be practiced. In this regard, directional terminology, such as “top”, “bottom”, “front”, “back”, etc. may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concepts of the present disclosure are defined by the appended claims.

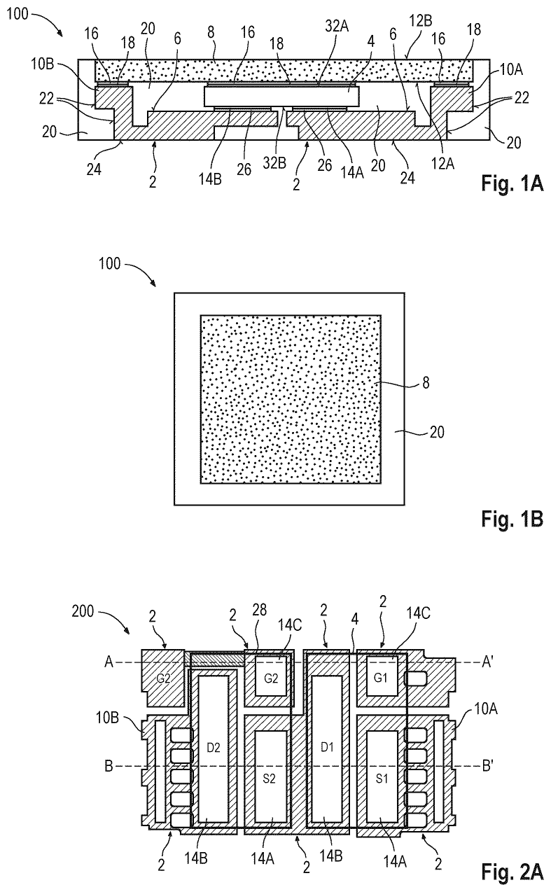

Referring now to FIG. 1, different views of a semiconductor device 100 in accordance with the disclosure are illustrated. More particular, FIG. 1A shows a sectional side view of the semiconductor device 100, while FIG. 1B shows a sectional top view of the semiconductor device 100. The semiconductor device 100 may include a leadframe 2, a semiconductor chip 4 arranged above a mounting surface 6 of the leadframe 2, and a heatsink 8 arranged above a top surface 32A of the semiconductor chip 4 facing away from the mounting surface 6 of the leadframe 2. At least one lead 10A, 10B of the leadframe 2 may extend towards a bottom surface 12A of the heatsink 8 facing the mounting surface 6 of the leadframe 2. The at least one lead 10A, 10B may be mechanically coupled to the bottom surface 12A of the heatsink 8.

The leadframe 2 is illustrated by hatched areas. The leadframe 2 may include one or more portions including the mounting surface 6 configured for mounting the semiconductor chip 4 thereon. The leadframe 2 may include a plurality of leads (or lead fingers or pins) 10A, 10B which may be at least partially arranged at a periphery of the mounting surface 6. In the side view of FIG. 1A, only two leads 10A, 10B are shown due to the chosen perspective. It is to be understood that the leadframe 2 may include additional leads which may be arranged behind the leads 10A, 10B and may thus be obscured. In the illustrated example, the mounting surface 6 may be provided by the leads 10A, 10B, i.e. the semiconductor chip 4 may be attached to the leads 10A, 10B, for example, by a technology called chip-on-leads. Therefore, no diepads (or die paddles) may be required in the shown case. However, in further examples, the leadframe 2 may include one or more diepads (or die paddles) including one or more mounting surfaces on which the semiconductor chip 4 may be mounted.

The leadframe 2 (i.e. the diepads and the leads 10A, 10B) may include or may be made of a metal or a metal alloy. For example, the leadframe 2 may include a core material including at least one of copper, copper alloy, aluminum, aluminum alloy, or the like. Optionally, the leadframe 2 may be plated with at least one plating material which may, for example, include at least one of nickel, nickel-phosphorous, nickel-nickel-phosphorous, copper, silver, or the like. In some examples, the leadframe 2 may optionally correspond to a half-etched leadframe.

In the side view of FIG. 1A, only a single semiconductor chip 4 is shown.

However, it is to be understood that the semiconductor device 100 may include additional semiconductor chips depending on the considered application. In general, the semiconductor chips described herein may be manufactured from an elemental semiconductor material (e.g. Si) or from a wide band gap semiconductor material or a compound semiconductor material (e.g. SiC, GaN, SiGe, GaAs). In some examples, lateral semiconductor chips, such as GaN chips, may be particularly suitable for utilizing the present disclosure. The semiconductor chips may be of arbitrary types and may include integrated circuits with active electronic components and/or passive electronic components. The integrated circuits may be designed as logic integrated circuits, analog integrated circuits, mixed signal integrated circuits, power integrated circuits, memory circuits, integrated passives, etc. Note that, throughout this description, the terms “chip”, “semiconductor chip”, “die”, “semiconductor die” may be used interchangeably.

In particular, the semiconductor chips described herein may be power semiconductor chips. In this context, the term “power semiconductor chip” may refer to a semiconductor chip providing at least one of high voltage blocking or high current-carrying capabilities. A power semiconductor chip may be configured for high currents having a maximum current value of a few Amperes, such as e.g. 10 A, or a maximum current value of up to or exceeding 100 A. Similarly, voltages associated with such current values may have values of a few Volts to a few tens or hundreds or even thousands of Volts, such as e.g. about 1200V, about 1600V, about 2400V, or the like. Power semiconductor chips may be used in any kind of power application like e.g. MOSFETs (Metal Oxide Semiconductor Field Effect Transistors), HEMTs (High Electron Mobility Transistors), half bridge circuits, power modules including a gate driver, etc. For example, power semiconductor chips may include or may be part of a power device like e.g. a power MOSFET, an LV (low voltage) power MOSFET, a power IGBT (Insulated Gate Bipolar Transistor), a power diode, a power HEMT, a superjunction power MOSFET, or the like.

In the illustrated example, the semiconductor chip 4 may particularly correspond to a lateral power semiconductor chip including electrical contacts 14A, 14B arranged on the bottom surface 32B of the semiconductor chip 4. In the side view of FIG. 1A, only two electrical contacts 14A, 14B are shown due to the chosen perspective, but the semiconductor chip 4 may include additional electrical contacts depending on the specific chip type. In a non-limiting example, the semiconductor chip 4 may correspond to a power transistor chip. In some examples, the electrical contacts of the semiconductor chip 4 may include a gate contact, a drain contact and a source contact. In other examples, the electrical contacts of the semiconductor chip 4 may include a base contact, a collector contact and an emitter contact.

The heatsink 8 is illustrated by dotted areas. The heatsink 8 may include or may be made of a thermally conductive and electrically insulating material. In particular, the heatsink 8 may include or may be made of a ceramic material. In some examples, the heatsink 8 may include a ceramic core material (or ceramic core body) and electrically conductive layers arranged above the bottom surface 12A and/or the top surface 12B of the heatsink 8 (or the ceramic core material). In particular, the electrically conductive layers may be patterned. In this regard, the heatsink 8 may include or may correspond to at least one of a direct bonded copper substrate, an active metal brazing substrate, a silicon nitride ceramic substrate, an alumina ceramic substrate, an aluminum nitride ceramic substrate, or the like.

In the illustrated example, the heatsink 8 may include a metal layer 16 arranged above the bottom surface 12A of the heatsink 8. For example, the metal layer 16 may include or may correspond to a metal plating, which may be made of or may include copper or alloys thereof. It is to be noted that the metal layer 16 does not necessarily cover the entire bottom surface 12A of the heatsink 8, but may particularly be arranged at positions where the heatsink 8 is to be connected to the top surface 32A of the semiconductor chip 4 and/or to the top surfaces of the leads 10A, 10B. Optionally, a further material layer (not illustrated) may be arranged above the top surface 12B of the heatsink 8. For example, such additional material layer may include a solderable material or may correspond to an adhesive layer, such that optionally an additional heatsink (not illustrated) may be mounted on this material layer. It is to be noted that such additional heatsink may differ from the heatsink 8 as follows. While the heatsink 8 may be regarded as an internal heatsink of the semiconductor device 100, which may e.g. be embedded in an encapsulation material of the device, an additional heatsink arranged above the top surface 12B of the heatsink 8 may be regarded as an external heatsink. While the heatsink 8 may be included in the semiconductor device 100 during its fabrication, the additional heatsink may e.g. be attached to the semiconductor device 100 after its fabrication.

In the illustrated example, the first lead 10A may be electrically coupled to the first electrical contact 14A of the semiconductor chip 4, while the second lead 10B may be electrically coupled to the second electrical contact 14B of the semiconductor chip 4. That is, the electrical contacts 14A, 14B of the semiconductor chip 4 may be electrically accessible via the leads 10A, 10B. In this regard, an electrically conductive material 26 (such as e.g. a solder material or electrically conductive glue) may be configured to provide an electrical and mechanical connection between the leadframe 2 and the electrical contacts 10A, 10B of the semiconductor chip 4.

Each of the leads 10A, 10B may be mechanically coupled to the bottom surface of the metal layer 16. For this purpose, the leads 10A, 10B may be e.g. bent in an upward direction towards the bottom surface of the metal layer 16. In a similar fashion, the top surface 32A of the semiconductor chip 4 may be mechanically coupled to the bottom surface of the metal layer 16. The leads 10A, 10B and/or the semiconductor chip 4 may be mechanically coupled to the metal layer 16 by any appropriate technique. In particular, the leads 10A, 10B and the top surface 32A of the semiconductor chip 4 may be mechanically coupled to the metal layer 16 by at least one of soldering, sintering or high thermal conductivity glue, or the like. In this context, additional material layers 18 may be arranged on the top surfaces of the semiconductor chip 4 and/or the leads 10A, 10B for supporting the mechanical connection depending on the applied technique. For example, the material layers 18 may include or may correspond to a solder material or high thermal conductivity glue.

The semiconductor device 100 may include an encapsulation material 20. The encapsulation material 20 may include or may be made of at least one of an epoxy, a filled epoxy, a glass fiber filled epoxy, an imide, a thermoplast, a thermoset polymer, a polymer blend, a laminate, a mold compound, or the like. Various techniques may be used for encapsulating components in the encapsulation material 20, for example at least one of compression molding, injection molding, powder molding, liquid molding, map molding, laminating, or the like.

The encapsulation material 20 may at least partially encapsulate the leadframe 2, the semiconductor chip 4 and the heatsink 8. In the illustrated example, all side surfaces 22 of the leads 10A, 10B extending towards the bottom surface 12A of the heatsink 8 may be fully covered by the encapsulation material 20. Alternatively, at least one of the side surfaces 22 of the leads 10A, 10B may be at least partially uncovered by the encapsulation material 20. Exposed side surfaces of the leads 10A, 10B may support heat dissipation and thus a cooling of the semiconductor device 100.

A bottom surface 24 of the leadframe 2 opposite the mounting surface 6 of the leadframe 2 may be at least partially uncovered by the encapsulation material 20. The leads 10A, 10B may thus be accessible from outside of the encapsulation material 20. The exposed portions of the bottom surface 24 of the leadframe 2 may form electrical terminals of the semiconductor device 100. In this context, the semiconductor device 100 may correspond to a leadless semiconductor package. For example, the semiconductor device 100 may be mounted on a printed circuit board (not illustrated) via the exposed portions of the bottom surface 24 of the leadframe 2. Further, because the heatsink 8 itself can transfer heat and is physically coupled with the leads 10A and 10B, the heat can dissipate both from the bottom of the package, via the exposed part of the leads 10A and 10B, and from the top of the package, via the heatsink 8. Therefore it forms a double side cooling package.

The top surface 12B of the heatsink 8 may be at least partially (and in particular fully) uncovered by the encapsulation material 20. An exposed top surface 12B may support heat dissipation and thus a cooling of the semiconductor device 100. Since both the top surface 12B of the heatsink 8 and the bottom surface 24 of the leadframe 2 may be exposed, the semiconductor device 100 may be cooled from at least two sides, i.e. a dual cool feature may be provided.

During an operation of the semiconductor device 100, heat may be generated. The generated heat may be transported towards the heatsink 8 in two ways. First, the heat may be transported directly from the top surface 32A of the semiconductor chip 4 to the heatsink 8. Second, the heat may be transported from the bottom surface 32B of the semiconductor chip 4 to the heatsink 8 via the upward extending leads 10A, 10B. In some examples, in particular, a source pad and/or a drain pad of the semiconductor chip 4 may form a heat source. Therefore, the upward extending leads 10A, 10B may particularly correspond to drain leads and/or source leads contacting these heat sources for thermal dissipation. Due to such enhanced thermal dissipation, a thermal performance of the semiconductor device 100 may be increased as compared to conventional semiconductor devices.

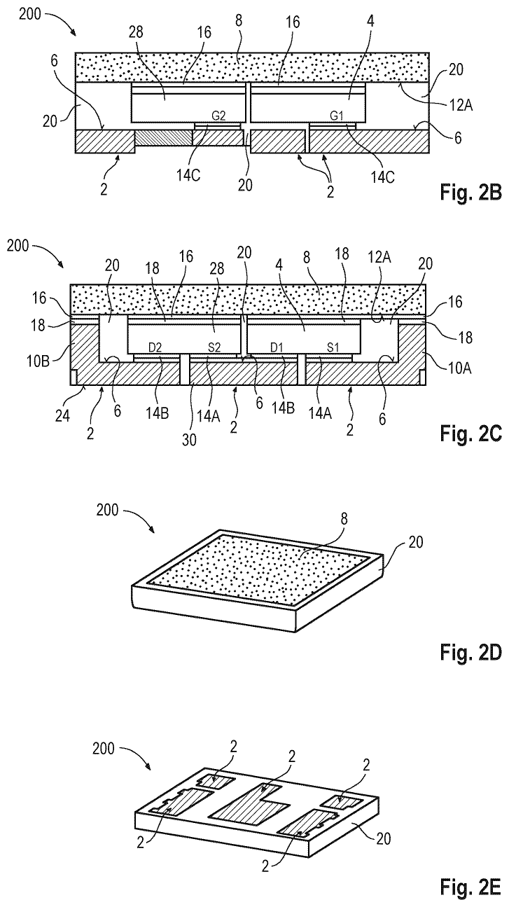

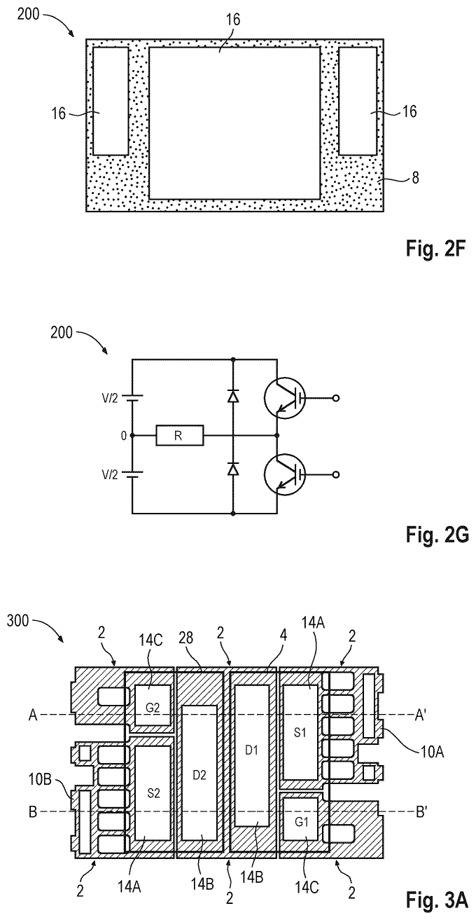

Referring now to FIG. 2, different views and a circuit diagram of a semiconductor device 200 in accordance with the disclosure are illustrated. More particular, FIG. 2A shows a sectional top view of the semiconductor device 200, FIG. 2B shows a first sectional side view of the semiconductor device 200 along a first sectional plane A-A′ in FIG. 2A, FIG. 2C shows a second sectional side view of the semiconductor device 200 along a second sectional plane B-B′ in FIG. 2A, FIG. 2D shows a perspective top view of the semiconductor device 200, FIG. 2E shows a perspective bottom view of the semiconductor device 200, FIG. 2F shows a sectional bottom view of the semiconductor device 200 (more particular, FIG. 2F shows a bottom view of a heatsink included in the semiconductor device 200), and FIG. 2G shows a circuit diagram of the semiconductor device 200. The semiconductor device 200 may include some or all features of other semiconductor devices in accordance with the disclosure described herein.

The semiconductor device 200 may include a first semiconductor chip 4 and a second semiconductor chip 28 arranged above the mounting surface 6 of the leadframe 2. In the illustrated example, each of the semiconductor chips 4, 28 may correspond to a lateral power chip including a source contact 14A (see S1, S2), a drain contact 14B (see D1, D2) and a gate contact 14C (see G1, G2). As can be seen from the view of FIG. 2A, the electrical contacts 14A to 14C of the semiconductor chips 4, 28 may have a same layout. The feature of the two semiconductor chips 4, 28 having the same layout may result in a cost advantage for the whole package 200, since the package 200 does not necessarily need to incorporate two different semiconductor chips in this arrangement. The semiconductor chips 4, 28 may be arranged on the mounting surface 6 in a side by side manner with a same orientation of the electrical contacts 14A to 14C. However, in further examples, the electrical contacts 14A to 14C of the semiconductor chips 4, 28 may have different layouts.

At least one first lead 10A of the leadframe 2 may be electrically coupled to the source contact 14A of the first semiconductor chip 4 (see S1). The first lead 10A may extend towards the bottom surface 12A of the heatsink 8 and may be mechanically coupled to the bottom surface 12A. In addition, at least one second lead 10B of the leadframe 2 may be electrically coupled to the drain contact 14B of the second semiconductor chip 28 (see D2). The second lead 10B may extend towards the bottom surface 12A of the heatsink 8 and may be mechanically coupled to the bottom surface 12A. During an operation of the semiconductor device 200, heat may be transported from the bottom surfaces of the semiconductor chips 4, 28 to the heatsink 8 via the leads 10A, 10B as previously described in connection with FIG. 1.

FIG. 2D shows an exemplary top view of the semiconductor device 200 having an exposed top surface of the heatsink 8. In some examples, a big metal layer may be arranged on the top surface of the heatsink 8, for the benefit of attaching a big external heat sink to it. For example, this big metal layer may include or may be made of copper or copper alloys and may form a solderable top surface of the heatsink 8, such that an external heat sink may be soldered to it. In some cases, the big metal layer may substantially cover the entire top surface of the heatsink 8.

FIG. 2F shows an exemplary patterning of the metal layer 16 arranged on the bottom surface 12A of the heatsink 8. Here, a middle portion may be configured to be connected to one or more semiconductor chips, while the peripheral portions may be configured to be connected to leads. For example, the left peripheral portion of the metal layer 16 may be connected to a drain lead, while the right peripheral portion of the metal layer 16 may be connected to a source lead. In some examples, the patterned metal layer 16 may include or may be made of copper or copper alloys (e.g. a copper layer of a DCB). In particular, copper may be used, if a soldering process is used for connecting to the heatsink 8. Alternatively, or additionally, in further examples, the metal layer 16 may include or may be made of silver or silver alloys. In particular, silver may be used, if a sintering process is used for connecting to the heatsink 8. In some examples, a single sintering process may be used for both, attaching the semiconductor chips 4, 28 to the leadframe 2 and attaching the leads 10A, 10B to the heatsink 8. It is to be noted that the metal layer 16 may be patterned into multiple discontinued metal areas, so that the electrical contacts 14A, 14B are not shorted due to the metal layer 16.

The leadframe 2 may include a portion 30 electrically coupling the first semiconductor chip 4 and the second semiconductor chip 28. More particular, the leadframe portion 30 may electrically couple the drain contact 14B of the first semiconductor chip 4 (see D1) and the source contact 14A of the second semiconductor chip 28 (see S2). The first semiconductor chip 4 and the second semiconductor chip 28 may form part of a low side switch and a high side switch of a half bridge circuit as it is exemplarily illustrated in the circuit diagram of FIG. 2G. It is noted that the circuit of FIG. 2G is non-limiting and, in particular, for illustrative purposes. The semiconductor device 200 may not necessarily include all components of the shown circuitry.

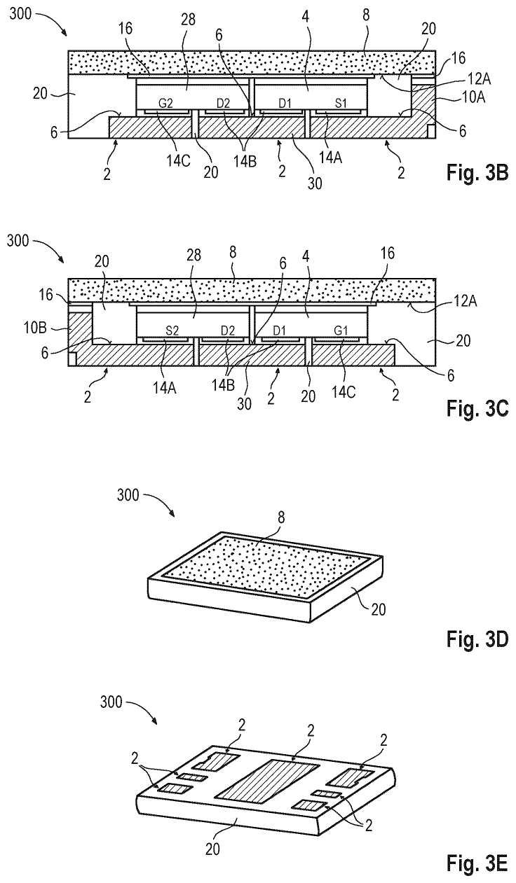

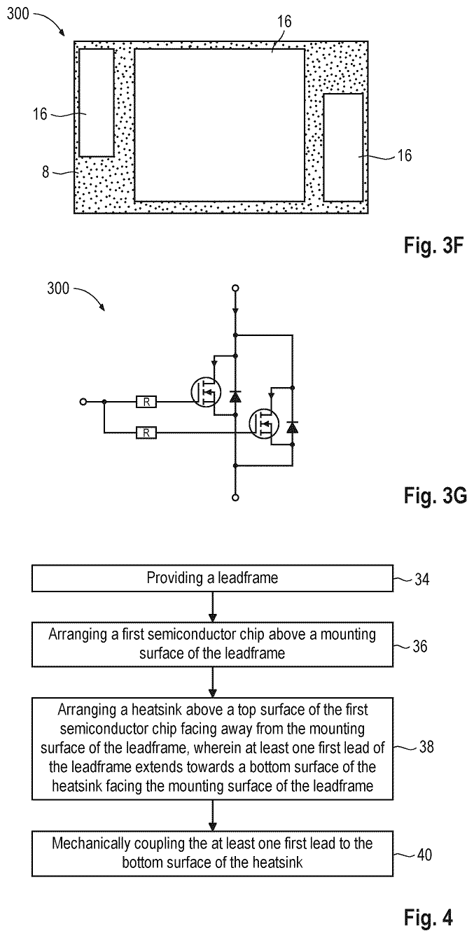

Referring now to FIG. 3, different views and a circuit diagram of a semiconductor device 300 in accordance with the disclosure are illustrated. More particular, FIG. 3A shows a sectional top view of the semiconductor device 300, FIG. 3B shows a first sectional side view of the semiconductor device 300 along a first sectional plane A-A′ in FIG. 3A, FIG. 3C shows a second sectional side view of the semiconductor device 300 along a second sectional plane B-B′ in FIG. 3A, FIG. 3D shows a perspective top view of the semiconductor device 300, FIG. 3E shows a perspective bottom view of the semiconductor device 300, FIG. 3F shows a sectional bottom view of the semiconductor device 300 (more particular, FIG. 3F shows a bottom view of a heatsink included in the semiconductor device 300), and FIG. 3G shows a circuit diagram of the semiconductor device 300. The semiconductor device 300 may include some or all features of other semiconductor devices in accordance with the disclosure described herein. In particular, previous comments made in connection with FIG. 2 may also hold true for the example of FIG. 3.

Similar to the example of FIG. 2, the semiconductor device 300 may include two lateral power chips 4 and 28, each including a source contact 14A (see S1, S2), a drain contact 14B (see D1, D2) and a gate contact 14C (see G1, G2). As can be seen from the view of FIG. 3A, the electrical contacts 14A to 14C of the semiconductor chips 4, 28 may have a same layout. The semiconductor chips 4, 28 may be arranged on the mounting surface 6 in a side by side manner, wherein the first semiconductor chip 4 may be rotated in the mounting surface 6 relative to the second semiconductor chip 28 by an angle of about 180 degrees. However, in further examples, the electrical contacts 14A to 14C of the semiconductor chips 4, 28 may have different layouts.

At least one first lead 10A of the leadframe 2 may be electrically coupled to the source contact 14A of the first semiconductor chip 4 (see S1). In a similar fashion, at least one second lead 10B of the leadframe 2 may be electrically coupled to the source contact 14B of the second semiconductor chip 28 (see S2). Each of the leads 10A, 10B may extend towards the bottom surface 12A of the heatsink 8 and may be mechanically coupled to the bottom surface 12A. During an operation of the semiconductor device 200, heat may be transported from the bottom surfaces of the semiconductor chips 4, 28 to the heatsink 8 via the leads 10A, 10B as previously described in connection with e.g. FIG. 1.

The leadframe 2 may include a portion 30 electrically coupling the first semiconductor chip 4 and the second semiconductor chip 28. More particular, the leadframe portion 30 may electrically couple the drain contact 14B of the first semiconductor chip 4 (see D1) and the drain contact 14A of the second semiconductor chip 28 (see D2). The first semiconductor chip 4 and the second semiconductor chip 28 may form part of a common drain circuit as it is exemplarily illustrated in the circuit diagram of FIG. 3G. It is noted that the circuit of FIG. 3G is non-limiting and, in particular, for illustrative purposes. The semiconductor device 300 may not necessarily include all components of the shown circuitry.

Referring now to FIG. 4, a flowchart of a method for manufacturing a semiconductor device in accordance with the disclosure is illustrated. The method is described in a general manner in order to qualitatively specify aspects of the disclosure. The method may be used for manufacturing semiconductor devices in accordance with the disclosure as described herein. The method may be extended by one or more further aspects, for example any of the aspects described in connection with other examples discussed herein. It is to be understood that a chronological order of the discussed method steps may be swapped or changed if technically possible and meaningful.

At 34, a leadframe may be provided. At 36, a first semiconductor chip may be arranged above a mounting surface of the leadframe. At 38, a heatsink may be arranged above a top surface of the first semiconductor chip facing away from the mounting surface of the leadframe. At least one first lead of the leadframe may extend towards a bottom surface of the heatsink facing the mounting surface of the leadframe. At 40, the at least one first lead may be mechanically coupled to the bottom surface of the heatsink.

In the following, semiconductor devices in accordance with the disclosure and methods for manufacturing such semiconductor devices are described by means of examples.

Example 1 is a semiconductor device, comprising: a leadframe; a first semiconductor chip arranged above a mounting surface of the leadframe; and a heatsink arranged above a top surface of the first semiconductor chip facing away from the mounting surface of the leadframe, wherein at least one first lead of the leadframe extends towards a bottom surface of the heatsink facing the mounting surface of the leadframe, and wherein the at least one first lead is mechanically coupled to the bottom surface of the heatsink.

Example 2 is a semiconductor device according to Example 1, wherein the heatsink comprises a ceramic material.

Example 3 is a semiconductor device according to Example 1 or 2, wherein the heatsink comprises a thermally conductive and electrically insulating core material and at least one electrically conductive layer arranged above at least one of the bottom surface or the top surface of the heatsink.

Example 4 is a semiconductor device according to any of the preceding Examples, wherein the at least one first lead is electrically coupled to a first electrical contact of the first semiconductor chip arranged on a bottom surface of the first semiconductor chip facing the mounting surface of the leadframe.

Example 5 is a semiconductor device according to any of the preceding Examples, further comprising: a metal layer arranged above the bottom surface of the heatsink, wherein the metal layer is patterned into multiple discontinued metal areas, so that the electrical contacts are not shorted due to the metal layer.

Example 6 is a semiconductor device according to Example 5, wherein the at least one first lead is mechanically coupled to the metal layer.

Example 7 is a semiconductor device according to Example 5 or 6, wherein the top surface of the first semiconductor chip is mechanically coupled to the metal layer.

Example 8 is a semiconductor device according to Example 6 and/or 7, wherein the at least one first lead and/or the top surface of the first semiconductor chip are mechanically coupled to the metal layer by at least one of soldering, sintering or high thermal conductivity glue.

Example 9 is a semiconductor device according to any of the preceding Examples, wherein the first semiconductor chip is a lateral power semiconductor chip comprising electrical contacts arranged on the bottom surface of the first semiconductor chip.

Example 10 is a semiconductor device according to any of the preceding Examples, further comprising: an encapsulation material at least partially encapsulating the leadframe, the first semiconductor chip and the heatsink, wherein all side surfaces of the at least one first lead extending towards the bottom surface of the heatsink are fully covered by the encapsulation material.

Example 11 is a semiconductor device according to any of Examples 1 to 9, further comprising: an encapsulation material at least partially encapsulating the leadframe, the first semiconductor chip and the heatsink, wherein a side surface of the at least one first lead extending towards the bottom surface of the heatsink is at least partially uncovered by the encapsulation material.

Example 12 is a semiconductor device according to Example 10 or 11, wherein a top surface of the heatsink opposite the bottom surface of the heatsink is at least partially uncovered by the encapsulation material.

Example 13 is a semiconductor device according to any of Examples 10 to 12, wherein a bottom surface of the leadframe opposite the mounting surface of the leadframe is at least partially uncovered by the encapsulation material.

Example 14 is a semiconductor device according to any of the preceding Examples, wherein the heatsink comprises at least one of a direct bonded copper substrate, an active metal brazing substrate, a silicon nitride ceramic substrate, an alumina ceramic substrate, an aluminum nitride ceramic substrate.

Example 15 is a semiconductor device according to any of the preceding Examples, further comprising: a second semiconductor chip arranged above the mounting surface of the leadframe; and at least one second lead of the leadframe extending towards the bottom surface of the heatsink, wherein the at least one second lead is mechanically coupled to the bottom surface of the heatsink, and wherein the at least one second lead is electrically coupled to an electrical contact of the second semiconductor chip arranged on the bottom surface of the second semiconductor chip.

Example 16 is a semiconductor device according to Example 15, wherein the first semiconductor chip and the second semiconductor chip are electrically coupled via a portion of the leadframe comprising the mounting surface of the leadframe.

Example 17 is a semiconductor device according to Example 16, wherein: the portion of the leadframe electrically couples a drain contact of the first semiconductor chip and a source contact of the second semiconductor chip, and the first semiconductor chip and the second semiconductor chip form part of a low side switch and a high side switch of a half bridge circuit respectively.

Example 18 is a semiconductor device according to Example 16, wherein: the portion of the leadframe electrically couples a drain contact of the first semiconductor chip and a drain contact of the second semiconductor chip, and the first semiconductor chip and the second semiconductor chip form part of a common drain circuit.

Example 19 is a semiconductor device according to any of Examples 15 to 18, wherein the electrical contacts of the first semiconductor chip and the electrical contacts of the second semiconductor chip have a same layout.

Example 20 is a semiconductor device according to any of the preceding Examples, wherein the semiconductor device is a leadless semiconductor package.

Example 21 is a semiconductor device according to any of Examples 1 to 14, further comprising: at least one second lead of the leadframe extending towards the bottom surface of the heatsink, wherein the at least one second lead is mechanically coupled to the bottom surface of the heatsink, and wherein the at least one second lead is electrically coupled to a second electrical contact of the first semiconductor chip arranged on the bottom surface of the first semiconductor chip.

Example 22 is a method for manufacturing a semiconductor device, the method comprising: providing a leadframe; arranging a first semiconductor chip above a mounting surface of the leadframe; arranging a heatsink above a top surface of the first semiconductor chip facing away from the mounting surface of the leadframe, wherein at least one first lead of the leadframe extends towards a bottom surface of the heatsink facing the mounting surface of the leadframe; and mechanically coupling the at least one first lead to the bottom surface of the heatsink.

As employed in this description, the terms “connected”, “coupled”, “electrically connected”, and/or “electrically coupled” may not necessarily mean that elements must be directly connected or coupled together. Intervening elements may be provided between the “connected”, “coupled”, “electrically connected”, or “electrically coupled” elements.

Further, the words “over”, “on”, or the like, used with regard to e.g. a material layer formed or located “over” or “on” a surface of an object may be used herein to mean that the material layer may be located (e.g. formed, deposited, etc.) “directly on”, e.g. in direct contact with, the implied surface. The words “over” and “on” used with regard to e.g. a material layer formed or located “over” or “on” a surface may also be used herein to mean that the material layer may be located (e.g. formed, deposited, etc.) “indirectly on” the implied surface with e.g. one or more additional layers being arranged between the implied surface and the material layer.

Furthermore, to the extent that the terms “having”, “containing”, “including”, “with”, or variants thereof are used in either the detailed description or the claims, such terms are intended to be inclusive in a manner similar to the term “comprising”. That is, as used herein, the terms “having”, “containing”, “including”, “with”, “comprising”, and the like are open-ended terms that indicate the presence of stated elements or features, but do not preclude additional elements or features. The articles “a”, “an”, and “the” are intended to include the plural as well as the singular, unless the context clearly indicates otherwise.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the previous instances. In addition, the articles “a” and “an” as used in this application and the appended claims may generally be construed to mean “one or more” unless specified otherwise or clear from context to be directed to a singular form. Also, at least one of A and B or the like generally means A or B or both A and B.

Devices and methods for manufacturing devices are described herein. Comments made in connection with a described device may also hold true for a corresponding method and vice versa. For example, if a specific component of a device is described, a corresponding method for manufacturing the device may include a step of providing the component in a suitable manner, even if such step is not explicitly described or illustrated in the figures.

Although the disclosure has been shown and described with respect to one or more implementations, equivalent alterations and modifications will occur to others skilled in the art based at least in part upon a reading and understanding of this description and the annexed drawings. The disclosure includes all such modifications and alterations and is limited only by the concept of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or more other features of the other implementations as may be desired and advantageous for any given or particular application.

1. A semiconductor device, comprising:
a leadframe;
a first semiconductor chip arranged above a mounting surface of the leadframe; and
a heatsink arranged above a top surface of the first semiconductor chip facing away from the mounting surface of the leadframe,
wherein at least one first lead of the leadframe extends towards a bottom surface of the heatsink facing the mounting surface of the leadframe, and
wherein the at least one first lead is mechanically coupled to the bottom surface of the heatsink.

2. The semiconductor device of claim 1, wherein the heatsink comprises a ceramic material.

3. The semiconductor device of claim 1, wherein the heatsink comprises a thermally conductive and electrically insulating core material and at least one electrically conductive layer arranged above at least one of the bottom surface or the top surface of the heatsink.

4. The semiconductor device of claim 1, wherein the at least one first lead is electrically coupled to a first electrical contact of the first semiconductor chip arranged on a bottom surface of the first semiconductor chip facing the mounting surface of the leadframe.

5. The semiconductor device of claim 1, further comprising:
a metal layer arranged above the bottom surface of the heatsink, wherein the metal layer is patterned into multiple discontinued metal areas, so that the electrical contacts are not shorted due to the metal layer.

6. The semiconductor device of claim 5, wherein the at least one first lead is mechanically coupled to the metal layer.

7. The semiconductor device of claim 5, wherein the top surface of the first semiconductor chip is mechanically coupled to the metal layer.

8. The semiconductor device of claim 6, wherein the at least one first lead and/or the top surface of the first semiconductor chip are mechanically coupled to the metal layer by at least one of soldering, sintering or high thermal conductivity glue.

9. The semiconductor device of claim 1, wherein the first semiconductor chip is a lateral power semiconductor chip comprising electrical contacts arranged on the bottom surface of the first semiconductor chip.

10. The semiconductor device of claim 1, further comprising:
an encapsulation material at least partially encapsulating the leadframe, the first semiconductor chip (4) and the heatsink,
wherein all side surfaces of the at least one first lead extending towards the bottom surface of the heatsink are fully covered by the encapsulation material.

11. The semiconductor device of claim 1, further comprising:
an encapsulation material at least partially encapsulating the leadframe, the first semiconductor chip and the heatsink,
wherein a side surface of the at least one first lead extending towards the bottom surface of the heatsink is at least partially uncovered by the encapsulation material.

12. The semiconductor device of claim 10, wherein a top surface of the heatsink opposite the bottom surface of the heatsink is at least partially uncovered by the encapsulation material.

13. The semiconductor device of claim 12, wherein a bottom surface of the leadframe opposite the mounting surface of the leadframe is at least partially uncovered by the encapsulation material.

14. The semiconductor device of claim 1, wherein the heatsink comprises at least one of a direct bonded copper substrate, an active metal brazing substrate, a silicon nitride ceramic substrate, an alumina ceramic substrate, an aluminum nitride ceramic substrate.

15. The semiconductor device of claim 1, further comprising:
a second semiconductor chip arranged above the mounting surface of the leadframe; and
at least one second lead of the leadframe extending towards the bottom surface of the heatsink,
wherein the at least one second lead is mechanically coupled to the bottom surface of the heatsink, and
wherein the at least one second lead is electrically coupled to an electrical contact of the second semiconductor chip arranged on the bottom surface of the second semiconductor chip.

16. The semiconductor device of claim 15, wherein the first semiconductor chip and the second semiconductor chip are electrically coupled via a portion of the leadframe comprising the mounting surface of the leadframe.

17. The semiconductor device of claim 16, wherein:
the portion of the leadframe electrically couples a drain contact of the first semiconductor chip and a source contact of the second semiconductor chip, and
the first semiconductor chip and the second semiconductor chip form part of a low side switch and a high side switch of a half bridge circuit respectively.

18. The semiconductor device of claim 16, wherein:
the portion of the leadframe electrically couples a drain contact of the first semiconductor chip and a drain contact of the second semiconductor chip, and
the first semiconductor chip and the second semiconductor chip form part of a common drain circuit.

19. The semiconductor device of claim 15, wherein the electrical contacts of the first semiconductor chip and the electrical contacts of the second semiconductor chip have a same layout.

20. The semiconductor device of claim 1, wherein the semiconductor device is a leadless semiconductor package.

21. The semiconductor device of claim 1, further comprising:
at least one second lead of the leadframe extending towards the bottom surface of the heatsink,
wherein the at least one second lead is mechanically coupled to the bottom surface of the heatsink, and
wherein the at least one second lead is electrically coupled to a second electrical contact of the first semiconductor chip arranged on the bottom surface of the first semiconductor chip.

22. A method for manufacturing a semiconductor device, the method comprising:
providing a leadframe;
arranging a first semiconductor chip above a mounting surface of the leadframe;
arranging a heatsink above a top surface of the first semiconductor chip facing away from the mounting surface of the leadframe, wherein at least one first lead of the leadframe extends towards a bottom surface of the heatsink facing the mounting surface of the leadframe; and
mechanically coupling the at least one first lead to the bottom surface of the heatsink.
